(19) United States
(12) Patent Application Publication
(10) Pub. No.: US 2026/0203469 A1
(43) Pub. Date: Jul. 16, 2026

(54) METHOD FOR BUILDING PHOTOLITHOGRAPHY MODEL, DEVICE, MEDIUM, AND PRODUCT

(71) Applicant: DONGFANG JINGYUAN ELECTRON CO., LTD., Beijing (CN)

(72) Inventors: Ming Ding, Beijing (CN); Ke Xia, Beijing (CN)

(21) Appl. No.: 19/561,286

(22) Filed: Mar. 9, 2026

(30) Foreign Application Priority Data
Mar. 12, 2025 (CN) 202510293727.1

(51) Int. Cl. G06F 30/20

(52) U.S. Cl. CPC G06F 30/20

(57) ABSTRACT

The present application discloses a method and device for building a photolithography model, a medium, and a product, applied in the technical field of photolithography. In this method, one alignment error is configured to characterize an offset existing when a mask pattern sample is aligned with an actual photolithography pattern. When a first photolithography model is trained, the alignment error and parameters of the first photolithography model are iteratively adjusted until a cost function value satisfies an iteration stop condition; and then a photolithography model capable of accurate simulation is obtained. The alignment error is used as an unknown variable to be solved, and the value of this unknown variable is calibrated in each iteration of the model to obtain a relatively accurate alignment error value, and based on the alignment error value, a simulation pattern output by the model is aligned with the actual photolithography pattern.

### CROSS-REFERENCE TO RELATED APPLICATIONS

The present application claims priority to Chinese Patent Application No. 202510293727.1, titled “METHOD FOR BUILDING PHOTOLITHOGRAPHY MODEL, DEVICE, MEDIUM, AND PRODUCT” and filed on Mar. 12, 2025, which is hereby incorporated by reference in its entirety.

### TECHNICAL FIELD

The present application belongs to the technical field of photolithography, and in particular, relates to a method for building a photolithography model, device, a medium, and a product.

### BACKGROUND

In order to determine a photolithography model, model parameters need to be calibrated with actual exposure imaging data, so that model output results can accurately reflect an imaging process. In the parameter calibration process, relative positions of an actual photolithography pattern in a scanning electron microscope (SEM) image and a mask pattern need to be aligned, so the accuracy of the generated model relies on the alignment result. After the alignment is completed, the goal of parameter calibration is to reduce deviation between a model simulation pattern and the actual photolithography pattern in the SEM image. If there is an error in the alignment of the SEM image, the accuracy of the photolithography model will be greatly affected.

It can be seen that the current parameter calibration for the photolithography model relies on the accuracy of alignment between the mask pattern and the SEM image.

### SUMMARY

In one aspect, an embodiment of the present application provides a method for building a photolithography model, including:
acquiring a first photolithography model to be trained, a mask pattern sample, an actual photolithography pattern corresponding to the mask pattern sample, and an initial value of an alignment error;
iteratively adjusting the value of the alignment error and parameters of the first photolithography model until a cost function value satisfies an iteration stop condition, where the cost function value is determined based on a deviation value between a simulation pattern and the actual photolithography pattern; the simulation pattern is obtained by the first photolithography model simulating the mask pattern sample; the alignment error is used for aligning the simulation pattern with the actual photolithography pattern; and
determining the current first photolithography model as a photolithography model under a condition that the cost function value satisfies the iteration stop condition.

In another aspect, the first photolithography model includes a plurality of sub-models;
the iteratively adjusting the value of the alignment error and parameters of the first photolithography model until a cost function value satisfies an iteration stop condition, and determining the current first photolithography model as a photolithography model when the cost function value satisfies the iteration stop condition, include:
adjusting a first parameter group of the first photolithography model to obtain a corresponding second photolithography model under the first parameter group, where the first parameter group includes internal parameters of the sub-models;
iteratively adjusting the value of the alignment error and a second parameter group of the second photolithography model until a first cost function value satisfies a first iteration stop condition, where the second parameter group includes remaining parameters in the first photolithography model except the first parameter group; the first cost function value is determined based on a first simulation pattern and the actual photolithography pattern, and the first simulation pattern is obtained by the adjusted second photolithography model simulating the mask pattern sample; and
determining a second cost function value based on the mask pattern sample, the actual photolithography pattern, the finally obtained alignment error, and the finally obtained second photolithography model; under a condition that the second cost function value does not satisfy a second iteration stop condition, returning to the adjusting the first parameter group of the first photolithography model, until the second cost function value satisfies the second iteration stop condition; and
determining the finally obtained second photolithography model as the photolithography model when the second cost function value satisfies the second iteration stop condition.

In another aspect, the iteratively adjusting the value of the alignment error and a second parameter group of the second photolithography model until a first cost function value satisfies a first iteration stop condition includes:
adjusting the value of the alignment error and the second parameter group of the second photolithography model;
inputting the mask pattern sample into the adjusted second photolithography model to obtain the first simulation pattern;
aligning the first simulation pattern with the actual photolithography pattern based on the adjusted alignment error;
acquiring a difference in key dimensions between the aligned first simulation pattern and actual photolithography pattern to obtain a first deviation;
determining the first cost function value based on the first deviation; and
under a condition that the first cost function value does not satisfy the first iteration stop condition, returning to the adjusting the value of the alignment error and the second parameter group of the second photolithography model until the first cost function value satisfies the first iteration stop condition.

In another aspect, the first iteration stop condition includes: a difference between the first cost function value obtained in the current iteration and the first cost function value obtained in the previous iteration is less than a first threshold.

In another aspect, the adjusting the value of the alignment error and the second parameter group of the second photolithography model includes:
adjusting the value of the alignment error and the second parameter group of the second photolithography model within a first value range according to a gradient-based optimization algorithm.

In another aspect, the determining a second cost function value based on the mask pattern sample, the actual photolithography pattern, the finally obtained alignment error, and the finally obtained second photolithography model includes:
inputting the mask pattern sample into the finally obtained second photolithography model to obtain a second simulation pattern;
aligning the second simulation pattern with the actual photolithography pattern based on the finally obtained alignment error;
acquiring a difference in key dimensions between the aligned second simulation pattern and actual photolithography pattern to obtain a second deviation; and
determining the second cost function value based on the second deviation.

In another aspect, the second iteration stop condition includes: a difference between the second cost function value obtained in the current iteration and the second cost function value obtained in the previous iteration is less than a second threshold.

In another aspect, the adjusting a first parameter group of the first photolithography model to obtain a corresponding second photolithography model under the first parameter group includes:
adjusting the first parameter group of the first photolithography model within a second value range to obtain the second photolithography model according to a gradient-free nonlinear optimization algorithm.

In still another aspect, an embodiment of the present application further provides a device for building a photolithography model, including: a processor and a memory storing computer program instructions, where
the processor, when executing the computer program instructions, implements the method for building a photolithography model as described above.

In still another aspect, an embodiment of the present application further provides a computer-readable storage medium, where the computer-readable storage medium stores computer program instructions, and the computer program instructions, when executed by a processor, implement the method for building a photolithography model as described above.

In still another aspect, an embodiment of the present application further provides a computer program product, where instructions in the computer program product, when executed by a processor of an electronic device, enable the electronic device to perform the method for building a photolithography model as described in any of the above.

### BRIEF DESCRIPTION OF THE DRAWINGS

In order to explain the technical solutions of the embodiments of the present application more clearly, the accompanying drawings required for use in the embodiments of the present application will be briefly introduced below. A person of ordinary skill in the art may derive other drawings based on these drawings without any creative effort.

FIG. 1 illustrates a schematic flowchart of a first method for building a photolithography model according to an embodiment of the present application;

FIG. 2 illustrates a schematic flowchart of a second method for building a photolithography model according to an embodiment of the present application;

FIG. 3 illustrates a schematic diagram of an iteration process of an inner layer model according to an embodiment of the present application;

FIG. 4 illustrates a schematic diagram of a process of determining a second cost function value according to an embodiment of the present application; and

FIG. 5 illustrates a schematic diagram of a hardware structure of a device for building a photolithography model according to an embodiment of the present application.

### DETAILED DESCRIPTION

Features and exemplary embodiments of various aspects of the present application will be described in detail below. In order to make the objectives, technical solutions, and advantages of the present application clearer, the present application will be further described in detail below with reference to the accompanying drawings and specific embodiments. It should be understood that the specific embodiments described herein are merely intended to explain the present application, but not to limit the present application. For a person skilled in the art, the present application may be implemented without some of these specific details. The following descriptions of the embodiments are merely for providing a better understanding of the present application by showing examples of the present application.

It should be noted that the relational terms herein, such as first and second, are merely used for distinguishing one entity or operation from another, and do not necessarily require or imply that any actual relationship or sequence exists between these entities or operations. Moreover, the terms “include”, “comprise”, and any variants thereof are intended to cover a non-exclusive inclusion, such that a process, method, article, or device including a series of elements not only includes those elements, but further includes other elements not listed explicitly, or includes inherent elements of the process, method, article, or device. Without further limitations, the element defined by the statement “include . . . ” does not exclude the existence of other identical elements in a process, method, item, or device that includes that element.

Photolithography is a crucial step in a chip manufacturing process. Firstly, a light intensity distribution similar to a mask pattern is formed in a photoresist by using an optical system, and then a pattern consistent with a design pattern is formed on a silicon wafer through a series of physical and chemical reactions. However, as the device size continues to reduce and gradually approaches the resolution limit of the optical system, and due to the diffraction limited characteristic of a photolithography system, as well as various system aberrations, errors, and process deviations, the pattern formed in the silicon wafer deviates significantly from the design pattern, ultimately rendering the chip inoperable.

To solve this problem, the mask pattern used for exposure needs to be optimized and corrected, so that the pattern finally obtained in the silicon wafer is consistent with the design pattern. The optimization and correction of the mask requires building an accurate photolithography model in the foregoing imaging process, and performing iterative optimization under the guidance of the photolithography model to obtain the final mask pattern.

The photolithography model built in the present application may be applied to the above scenario. By simulating a photolithography process through the photolithography model, a simulation pattern corresponding to the mask pattern is obtained to guide an optical proximity effect correction process.

The purpose of the present application is to calibrate parameters of a photolithography model, so as to build the photolithography model that can achieve accurate simulation. In conventional solutions, a certain quantity of mask patterns and SEM images of these mask patterns after photolithography are first acquired, and then the parameters of the photolithography model are iteratively adjusted with the mask patterns as samples and actual photolithography patterns in the SEM images as labels, so that the finally obtained photolithography pattern can output simulation patterns that conform to the actual photolithography patterns.

In the parameter calibration process, relative positions of the actual photolithography pattern in the SEM image and the mask pattern need to be first aligned, so the accuracy of the subsequently generated photolithography model depends on the alignment result. However, in practical applications, due to the significant difference in shape between the mask pattern and the SEM image, it is difficult to achieve accurate alignment of the actual photolithography pattern with the mask pattern, resulting in low simulation accuracy of the photolithography model.

Consequently, it is excessively difficult to accurately align the actual photolithography pattern in the SEM image with the mask pattern, and there is inevitably an alignment error in the alignment process. Therefore, the present application proposes that since the alignment error cannot be eliminated, the alignment error can be introduced into an iterative training process of the model as a latent variable, where the value of the alignment error is continuously calibrated to obtain an accurate alignment error value, the simulation pattern output by the model is further aligned with the actual photolithography pattern based on the determined alignment error, and the model is trained based on these data to eliminate the impact of the alignment error on model training.

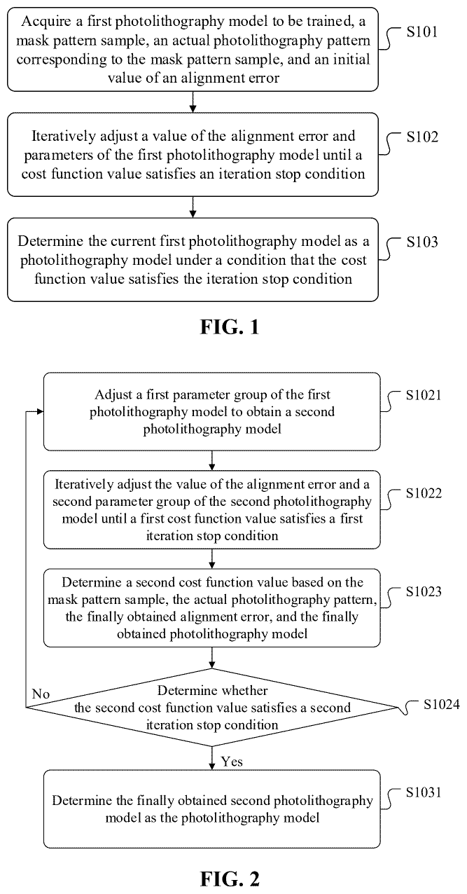

On this basis, the embodiments of the present application provide a method for building a photolithography model, device, medium, and product. Firstly, the method for building a photolithography model according to the embodiments of the present application will be introduced below. FIG. 1 illustrates a schematic flowchart of a first method for building a photolithography model according to an embodiment of the present application. As shown in FIG. 1, the method includes the following steps: S101 to S103.

S101: Acquire a first photolithography model to be trained, a mask pattern sample, an actual photolithography pattern corresponding to the mask pattern sample, and an initial value of an alignment error.

A photolithography process includes various types of reactions, such as optical imaging and physical and chemical reactions. Different reactions need to be simulated based on different sub-models. Therefore, the first photolithography model includes a plurality of sub-models. In practical applications, the first photolithography model including the plurality of sub-models is first built, and at the same time, initial values of model parameters in the first photolithography model are set.

Like the conventional photolithography model training scheme, the embodiments of the present application also need to first acquire a certain quantity of mask patterns and SEM images of these mask patterns after photolithography, where the mask patterns serve as model training samples, and actual photolithography patterns in the SEM images serve as labels.

The mask pattern samples correspond one to one with the actual photolithography patterns. In the training process, the mask pattern samples are usually input into the photolithography model, then differences between simulation patterns output by the model and the actual photolithography patterns are acquired, and the model parameters are adjusted based on the differences, so that the finally obtained model can output results that conform to the actual photolithography.

The alignment error is for characterizing an offset existing when the mask pattern sample is aligned with the actual photolithography pattern. In order to ensure the training effect of the model, when a first deviation between a simulation pattern and an actual photolithography pattern is acquired, it should be ensured that the two patterns are aligned. However, since the actual photolithography pattern is extracted from an SEM image, the mask pattern sample needs to be aligned with the actual photolithography pattern first, but there is a certain offset (i.e., alignment error) during alignment. In this scheme, in order to eliminate the alignment error, the value of the alignment error is calculated, and then the simulation pattern is aligned with the actual photolithography pattern by using the alignment error.

S102: Iteratively adjust the value of the alignment error and parameters of the first photolithography model until a cost function value satisfies an iteration stop condition.

In the embodiments of the present application, the cost function value is determined based on a deviation value between a simulation pattern and the actual photolithography pattern; and the simulation pattern is obtained by the first photolithography model simulating the mask pattern sample. When there is the significant deviation between the simulation pattern and the actual photolithography pattern, the simulation accuracy of the photolithography model is low and the parameters of the photolithography model need to be adjusted. Ultimately, the photolithography model can achieve more accurate simulation, with minimal deviation between the simulation pattern and the actual photolithography pattern.

The alignment error is induced when the mask pattern sample is aligned with the actual photolithography pattern in the SEM image. Due to limitations in alignment technology, alignment errors cannot be avoided in practical applications, and their values cannot be determined, and the impact of the alignment errors on model training cannot be eliminated, resulting in low model accuracy. The purpose of this embodiment is to obtain more accurate alignment error values through iterative model training, thereby eliminating their impact on model accuracy.

In this embodiment, the alignment error is used for aligning the simulation pattern with the actual photolithography pattern. In the case where the simulation pattern is not aligned with the actual photolithography pattern, the model training result is inevitably affected. In the present application, an alignment error parameter is designed in the model, and the simulation pattern is aligned with the actual photolithography pattern based on the alignment error parameter, thereby eliminating the impact of misalignment between the mask pattern sample and the actual photolithography pattern.

However, the accurate value of the alignment error cannot be directly obtained currently. Therefore, the present application calibrates the value of the alignment error during each iteration of the model to obtain a relatively accurate alignment error value, based on which the simulation pattern is aligned with the actual photolithography pattern to better eliminate the impact of misalignment between the mask pattern sample and the actual photolithography pattern.

S103: Determine the current first photolithography model as a photolithography model when the cost function value satisfies the iteration stop condition.

The cost function value satisfies the iteration stop condition, indicating that the model can now simulate more accurately. Therefore, the current first photolithography model is determined as the final photolithography model.

In the method for building a photolithography model according to the embodiments of the present application, one alignment error is defined to characterize an offset existing when the mask pattern sample is aligned with the actual photolithography pattern. When the first photolithography model is trained, the alignment error and the parameters of the first photolithography model are iteratively adjusted until the cost function value satisfies the iteration stop condition; and then the photolithography model capable of accurate simulation is obtained. Because the offset existing when the mask pattern sample is aligned with the actual photolithography pattern leads to an offset between the simulation pattern output by the model and the actual photolithography pattern during model training, the model training effect will be affected. Therefore, in the present application, the alignment error is used as an unknown variable to be solved, the value of this unknown variable is calibrated in each iteration of the model to obtain a relatively accurate alignment error value, and based on which the simulation pattern output by the model is aligned with the actual photolithography pattern, the impact of misalignment between the mask pattern sample and the actual photolithography pattern may be eliminated, thereby ensuring the model training effect and improving the simulation accuracy of the photolithography model.

The foregoing embodiments do not define the way to iteratively adjust the parameters of the first photolithography model and the alignment error. Because the parameters of the first photolithography model are numerous, if the adjustment method is irrational, the efficiency of model training will be relatively low. Therefore, some embodiments of the present application provide a specific implementation. FIG. 2 illustrates a schematic flowchart of a second method for building a photolithography model according to an embodiment of the present application. As shown in FIG. 2, S102 may include S1021 to S1024; and S103 may specifically include S1031.

S1021: Adjust a first parameter group of the first photolithography model to obtain a second photolithography model.

In the embodiments of the present application, the process of building a photolithography model is divided into two layers, with the first parameter group in the outer layer and a second parameter group in the inner layer. The first parameter group may include internal parameters of each sub-model; and the second parameter group may include other parameters excluding the first parameter group, such as a weight coefficient and a model threshold of each sub-model. The weight coefficient and the model threshold can be better adjusted after the internal parameters of each sub-model are first determined.

As mentioned earlier, the initial first photolithography model is first acquired. During parameter calibration, the first parameter group of the first photolithography model is first adjusted to obtain the second photolithography model. That is, in each iteration of the outer layer, the first parameter group needs to be adjusted once.

It should be noted that the values of parameters in the first parameter group are generally within reasonable ranges. Therefore, a search space for each parameter may be predefined, and in each iteration, a search may be conducted within the search space.

S1022: Iteratively adjust the value of the alignment error and a second parameter group of the second photolithography model until a first cost function value satisfies a first iteration stop condition.

The second parameter group includes a weight coefficient and a model threshold of each sub-model; and the first cost function value is determined based on a first simulation pattern and the actual photolithography pattern, the adjusted alignment error is used for aligning the first simulation pattern with the actual photolithography pattern, and the first simulation pattern is obtained by the adjusted second photolithography model simulating the mask pattern sample.

After the parameter values of the first parameter group in the outer layer are fixed, iterative adjustments are performed in the inner layer. In addition to adjusting the parameters of the second parameter group, the alignment error between the actual photolithography pattern and the mask pattern sample also needs to be adjusted in the inner layer.

The specific content of the first iteration stop condition is not limited and may be set according to actual needs. As an optional embodiment, a maximum number of iterations may be set, and the first iteration stop condition includes that the number of iterations reaches the maximum number. Convergence of the model may further be determined by the cost function value. For example, a deviation value between the simulation pattern output by the model and the actual photolithography pattern is calculated, the deviation value is input into the cost function to obtain a cost function value, and the convergence of the model is determined through the difference between the cost function values of two adjacent iterations. It should be noted that the convergence of the model merely represents that the second parameter group in the inner layer and the alignment error reach a local optimal solution.

As mentioned earlier, when the deviation value between the simulation pattern output by the model and the actual photolithography pattern is calculated, the alignment error between the mask pattern sample and the actual photolithography pattern also leads to an alignment error between the simulation pattern and the actual photolithography pattern, resulting in inaccurate calculation results, and thereby ultimately obtaining a photolithography model with lower accuracy. Therefore, when the deviation value is calculated, an alignment error value may be configured to characterize the alignment error between the mask pattern sample and the actual photolithography pattern, and based on the set alignment error, the simulation pattern is aligned with the actual photolithography pattern to eliminate the alignment error.

In this embodiment, the alignment error is used as an implicit variable in the inner iteration, the value of the alignment error can be calibrated in each iteration, and the accurate alignment error can further improve model accuracy, that is, the parameter value meeting the requirements. After the model accuracy is improved, the alignment error is adjusted in the next iteration again to obtain a more accurate value of the alignment error.

S1023: Determine a second cost function value based on the mask pattern sample, the actual photolithography pattern, the finally obtained alignment error, and the finally obtained second photolithography model.

S1024: Determine whether the second cost function value satisfies a second iteration stop condition; and when the second cost function value does not satisfy the second iteration stop condition, return to S1021; or when the second cost function value satisfies the second iteration stop condition, perform S1031.

S1031: Determine the finally obtained second photolithography model as the photolithography model.

Similarly, the specific content of the second iteration stop condition is not limited and may be set according to actual needs. As an optional embodiment, a maximum number of iterations may be set, and the second iteration stop condition includes that the number of iterations reaches the maximum number. Convergence of the model may further be determined by a cost function. For example, a deviation value between the simulation pattern output by the model and the actual photolithography pattern is calculated, the deviation value is input into the cost function to obtain a cost function value, and the convergence of the model is determined through the difference between the cost function values of two adjacent iterations.

In the embodiments of the present application, the values of the first parameter group are first fixed, and then the second parameter group and the alignment error are iteratively adjusted to obtain an optimal solution of the second parameter group and the alignment error under the current values of the first parameter group. It is determined whether the photolithography model converges under the current first parameter group and second parameter group. If the photolithography model does not converge, the values of the first parameter group are adjusted, and the second parameter group and the alignment error are iteratively adjusted again to obtain optimal solutions until the model converges. In this scheme, the process of adjusting model parameters is divided into an inner layer and an outer layer, the first parameter group in the outer layer is first adjusted to local optima, and then the second parameter group in the inner layer is adjusted, thereby improving model training efficiency.

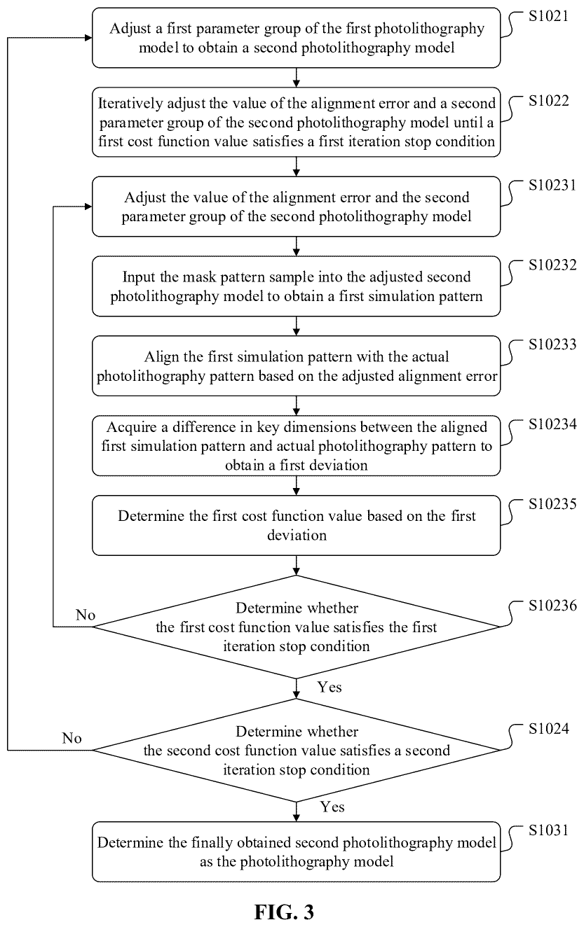

As mentioned earlier, in the present application, the model training is divided into an inner layer and an outer layer. For the iteration of the inner layer, an embodiment of the present application provides a specific implementation. FIG. 3 illustrates a schematic diagram of an iteration process of an inner layer model according to an embodiment of the present application. As shown in FIG. 3, S1023 may include S10231 to S10236.

S10231: Adjust the value of the alignment error and the second parameter group of the second photolithography model.

The values of both the second parameter group and the alignment error should be within rational ranges. Therefore, a search space for each parameter may be predefined, and in each iteration, a search may be conducted within the search space. This embodiment does not limit the way to adjust the second parameter group and the alignment error. As an optional embodiment, the second parameter group and the alignment error may be adjusted according to a gradient-based optimization algorithm to ensure the accuracy of solutions.

S10232: Input the mask pattern sample into the adjusted second photolithography model to obtain the first simulation pattern.

In this embodiment, the photolithography model is used for simulating a photolithography process. Therefore, after the mask pattern sample is input into the adjusted second photolithography model, the second photolithography model simulates the photolithography process to output the corresponding first simulation pattern.

S10233: Align the first simulation pattern with the actual photolithography pattern based on the adjusted alignment error.

In the embodiment of the present application, the way to determine the first deviation is not limited, as the alignment between the first simulation pattern and the actual photolithography pattern is based on the alignment between the mask pattern sample and the actual photolithography pattern. Based on the alignment deviation between the mask pattern sample and the actual photolithography pattern, the first simulation pattern may be aligned with the actual photolithography pattern.

S10234: Acquire a difference in key dimensions between the aligned first simulation pattern and actual photolithography pattern to obtain a first deviation.

This embodiment provides a specific scheme for iteratively adjusting the second parameter group and the alignment error. In the model iteration process, the simulation pattern is aligned with the actual photolithography pattern through the alignment error after each round of adjustment. Because a plurality of iterations can gradually improve the accuracy of the alignment error, the first deviation between the first simulation pattern and the actual photolithography pattern can be determined when the two are aligned. This ensures that the finally obtained second photolithography model achieves local optima, thereby improving the accuracy of the finally obtained photolithography model.

S10235: Determine the first cost function value based on the first deviation.

Further, after the first simulation pattern is aligned with the actual photolithography pattern, the difference in key dimensions between the two may be acquired, thereby obtaining the first deviation. Then the first deviation is input into a preset cost function to obtain the first cost function value.

S10236: Determine whether the first cost function value satisfies the first iteration stop condition; and when the first cost function value does not satisfy the first iteration stop condition, return to S1031; or when the first cost function value satisfies the first iteration stop condition, perform S1024.

The embodiment of the present application does not limit the specific content of the first iteration stop condition. As an optional embodiment, the first iteration stop condition may include: the difference between the first cost function value obtained in the current iteration and the first cost function value obtained in the previous iteration is less than a first threshold.

The magnitude of the first threshold is not limited, and may be set according to the actual situation. When the difference in cost function values between two adjacent iterations is less than the first threshold, the inner layer optimization of the model has been completed, and the optimal solutions of the second parameter group and the alignment error can be obtained under the current first parameter group.

In this embodiment, a specific example of the first iteration stop condition is provided, where an appropriate iteration stop condition is adopted to ensure quick solving and the accuracy of the obtained solutions. Moreover, the corresponding cost function value is determined through the first deviation, whether the inner layer iteration of the model converges can be accurately determined through the cost function value,
and the iteration is stopped accordingly in a timely manner. Therefore, this scheme improves model training efficiency.

This embodiment provides a specific scheme for iteratively adjusting the second parameter group and the alignment error, where a plurality of iterations ensures that the finally obtained second photolithography model achieves local optima.

The above does not limit the way to adjust the first parameter group of the first photolithography model. As an optional embodiment, the first parameter group of the first photolithography model may be adjusted according to a gradient-free nonlinear optimization algorithm to obtain the second photolithography model, thereby quickly obtaining more accurate parameter solutions.

In addition, the above provides a specific embodiment of the first iteration stop condition, and the specific content of the second iteration stop condition is also not limited. As an optional embodiment, the second iteration stop condition may include: the difference between the second cost function value obtained in the current iteration and the second cost function value obtained in the previous iteration is less than a second threshold. The magnitude of the second threshold may also be determined according to the actual situation.

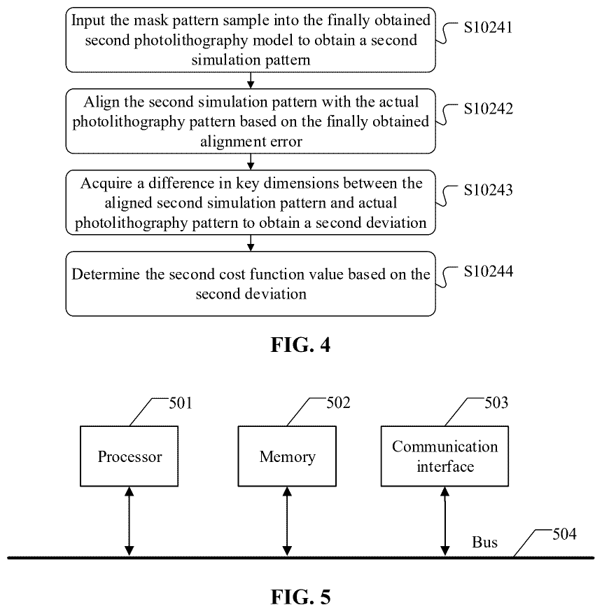

In practical applications, when whether the model converges is determined, the second cost function value needs to be determined. A specific determination scheme is provided here. FIG. 4 illustrates a schematic diagram of a process of determining a second cost function value according to an embodiment of the present application. As shown in FIG. 4, specifically, S1024 includes:

S10241: Input the mask pattern sample into the finally obtained second photolithography model to obtain a second simulation pattern.

The finally obtained second photolithography model is specifically obtained after the inner layer iteration is completed, that is, the optimal solutions of the second parameter group and the alignment error are determined. At this point, convergence of the outer layer iteration needs to be determined, so the mask pattern sample is input into the finally obtained second photolithography model to obtain the second simulation pattern.

S10242: Align the second simulation pattern with the actual photolithography pattern based on the finally obtained alignment error.

S10243: Acquire a difference in key dimensions between the aligned second simulation pattern and actual photolithography pattern to obtain a second deviation.

Similarly, the alignment between the second simulation pattern and the actual photolithography pattern is based on the alignment between the mask pattern sample and the actual photolithography pattern. Based on the alignment deviation between the mask pattern sample and the actual photolithography pattern, the second simulation pattern may be aligned with the actual photolithography pattern to obtain the second deviation.

S10244: Determine the second cost function value based on the second deviation.

In this embodiment, the corresponding cost function value is determined through the second deviation, whether the outer layer iteration of the model converges can be accurately determined through the cost function value, and the iteration is stopped accordingly in a timely manner, thereby improving model training efficiency.

In this embodiment, the corresponding cost function value is determined through the second deviation, whether the entire model converges can be accurately determined through the corresponding cost function value, and the iteration is stopped accordingly in a timely manner. Therefore, this scheme improves model training efficiency.

Hereinafter, a specific embodiment is provided to illustrate the method for building a photolithography model according to the present application. The photolithography model may be expressed in the following form:

$$AI ( x , y ) = {F}_{0} ( mask , {\vec{γ}}_{0} ) \qquad ( 1 )$$

$$RI ( x , y ) = {c}_{1} \times {F}_{1} ( AI , {\vec{γ}}_{1} ) + {c}_{2} \times {F}_{2} ( AI , {\vec{γ}}_{2} ) + … + {c}_{m} \times {F}_{m} ( AI , {\vec{γ}}_{m} ) - t \qquad ( 2 )$$

Where AI(x,y) represents a spatial image formed at a position in a photoresist by incident light passing through a mask and an optical system, F₀( . . . ) represents a spatial image calculation model, mask represents the adopted mask pattern, and \vec{γ}₀ represents a parameter group to be calibrated in the model (usually including a defocus distance of the optical system, an imaging position in the photoresist, etc.).

RI(x,y) represents a developed image, and the contour of a pattern obtained by photolithography is formed by connecting points with a value of 0 on the image. Fᵢ( . . . ) i=1, 2, 3, . . . , m represents a semi-empirical model expression, referred to as an i^{th} model component, with a basic image as input (without loss of generality, here the spatial image or a pixelated image of the mask is used as input), and \vec{γ}ᵢ represents a parameter to be calibrated for the model component (first parameter group). cᵢ represents a weight coefficient of the corresponding model component, t represents a threshold, and cᵢ and t represent the second parameter group.

The semi-empirical model expression may be in various forms. For example, the semi-empirical model expression may be a Gaussian convolution performed on an input image to simulate a diffusion process, as described by the following equation:

$${F}_{k} ( AI , {\vec{γ}}_{k} ) = AI ( x , y ) ⊗ exp \frac{{x}^{2} + {y}^{2}}{2 {( {g}_{k} )}^{2}} \qquad ( 3 )$$

Where ⊗ represents a convolution operation,

$$exp \frac{{x}^{2} + {y}^{2}}{2 {( {g}_{k} )}^{2}}$$

represents a Gaussian convolution kernel, and gₖ represents a parameter to be calibrated.

The first parameter group may be optimized by using a gradient-free nonlinear optimization algorithm engine (such as a genetic algorithm, a simulation annealing algorithm, or a nonlinear optimization library). Firstly, a search space for each parameter in the first parameter group is given, and the nonlinear algorithm engine generates candidate seed parameters to determine values of the parameters in the first parameter group in the current iteration.

At this point, basic model component images under the selected parameter seeds may be calculated, and then based on these images, optimization search of the second parameter group may be carried out to obtain a minimum cost function when the first parameter group is selected as a candidate seed, that is, obtain an optimal solution of the second parameter group in the current iteration. Then the optimization result is fed back to the gradient-free nonlinear optimization algorithm engine, and convergence is determined. If the optimization converges, the obtained model parameters are output. If the optimization does not converge, the first parameter group seed is further generated and the optimization search is continued.

For optimization search of the second parameter group, if model component images F₁(x,y), F₂(x, y), . . . , Fₘ(x,y) have been calculated under the determined first parameter group, the developed image may be represented as:

$$RI ( x , y ) = {c}_{1} \times {F}_{1} ( x , y ) + {c}_{2} \times {F}_{2} ( x , y ) + … + {c}_{m} \times {F}_{m} ( x , y ) - t \qquad ( 4 )$$

For the 1^{st} contour calibration point, its coordinates are (xₗ, yₗ), and its normal vector is (nxₗ, nyₗ). The contour point comes from the d^{th} SEM image, and the alignment error between the actual photolithography pattern of the SEM image and the mask is (P_{d}, Q_{d}), where P_{d} and Q_{d} represent alignment errors in an x direction and a y direction respectively, and their initial values are set to 0.

The alignment error of each SEM image and the second parameter group of the model are iteratively optimized. Under the alignment error value (P_{d}=\tilde{P}_{d}, Q_{d}=\tilde{Q}_{d}) of the current SEM image, the second deviation of the lth calibration point is:

$${EPE}_{l} \approx - \text{?} \qquad ( 5 )$$

$${RI}_{l} \approx RI ( {x}_{l} + {\tilde{P}}_{d} , {y}_{l} + {\tilde{Q}}_{d} ) + \frac{\partial RI ( {x}_{l} + {\tilde{P}}_{d} , {y}_{l} + {\tilde{Q}}_{d} )}{\partial x} \cdot ( {P}_{d} - {\tilde{P}}_{d} ) + \frac{\partial RI ( {x}_{l} + {\tilde{P}}_{d} , {y}_{l} + {\tilde{Q}}_{d} )}{\partial y} \cdot ( {Q}_{d} - {\tilde{Q}}_{d} ) \qquad ( 6 )$$

$${RI}_{l}^{′} \approx \frac{\partial RI ( {x}_{l} + \text{?} , {y}_{l} + {\tilde{Q}}_{d} )}{\partial x} \cdot {nx}_{l} + \frac{\partial RI ( {x}_{l} + {\tilde{P}}_{d} , {y}_{l} + \text{?} )}{\partial y} \cdot {nx}_{l} \qquad ( 7 )$$

$$Where :$$

$$RI ( {x}_{l} + {\tilde{P}}_{d} , {y}_{l} + {\tilde{Q}}_{d} ) = {c}_{1} + {F}_{1} ( {x}_{l} + {\tilde{P}}_{d} , {y}_{l} + {\tilde{Q}}_{d} ) + {c}_{1} + {F}_{2} ( {x}_{l} + {\tilde{P}}_{d} , {y}_{l} + \text{?} ) + … + {c}_{m} \times {F}_{m} ( {x}_{l} + \text{?} , {y}_{l} + \text{?} ) - t \qquad ( 8 )$$

$$\frac{\partial RI ( {x}_{l} + {\tilde{P}}_{d} , {y}_{l} + {\tilde{Q}}_{d} )}{\partial x} = {c}_{1} \times \frac{\partial {F}_{1} ( {x}_{l} + {\tilde{P}}_{d} , {y}_{l} + {\tilde{Q}}_{d} )}{\partial x} + {c}_{2} \times \frac{\partial {F}_{2} ( {x}_{l} + {\tilde{P}}_{d} , {y}_{l} + {\tilde{Q}}_{d} )}{\partial x} + … + {c}_{m} \times {c}_{1} \times \frac{\partial {F}_{m} ( {x}_{l} + {\tilde{P}}_{d} , {y}_{l} + {\tilde{Q}}_{d} )}{\partial x} \qquad ( 9 )$$

$$\frac{\partial RI ( {x}_{l} + \text{?} , {y}_{l} + {\tilde{Q}}_{d} )}{\partial y} = {c}_{1} \times \frac{\partial {F}_{1} ( {x}_{l} + {\tilde{P}}_{d} , {y}_{l} + {\tilde{Q}}_{d} )}{\partial y} + {c}_{2} \times \frac{\partial {F}_{2} ( {x}_{l} + {\tilde{P}}_{d} , {y}_{l} + {\tilde{Q}}_{d} )}{\partial y} + … + {c}_{m} \times {c}_{1} \times \frac{\partial {F}_{m} ( {x}_{l} + {\tilde{P}}_{d} , {y}_{l} + {\tilde{Q}}_{d} )}{\partial y} \qquad ( 10 )$$

$$Where {F}_{j} ( {x}_{l} + {\tilde{P}}_{d} , {y}_{l} + \text{?} ) , \frac{\text{?}}{\partial y} , and \frac{\text{?}}{\partial y} , j = 1 , 2 , … , m$$

$$\text{?} \text{indicates text missing or illegible when filed}$$

may be directly calculated from the model component images.

The above calculation results are substituted into a cost function:

$$Λ ( {c}_{1} , {c}_{2} , … , {c}_{m} , t , {P}_{1} , {Q}_{1} , … , {P}_{n} , {Q}_{n} ) = {\sum }_{l} {\vert {EPE}_{l} \vert}^{2} + others \qquad ( 11 )$$

The above cost function is a basic quadratic expression about model parameters c₁, c₂, . . . , cₘ, t and alignment errors of SEM images. By using the gradient-based optimization algorithm, the optimal solution of the cost function may be easily obtained.

Whether further rounds of optimization are needed is determined (usually by setting a maximum number of optimization iterations, where further optimization is carried out when the maximum number of iterations is not reached or when the cost function of the current round continues to decrease compared to the previous round). If the further optimization is needed, the alignment error values of the SEM images and the values of the second parameter group are updated for the next round of iteration optimization.

FIG. 5 illustrates a schematic diagram of a hardware structure of a device for building a photolithography model according to an embodiment of the present application. As shown in FIG. 5, the device for building a photolithography model may include a processor 501 and a memory 502 storing computer program instructions.

Specifically, the processor 501 may include a central processing unit (CPU) or an application specific integrated circuit (ASIC), or may be configured to implement one or more integrated circuits in the embodiments of the present application.

The memory 502 may include a mass memory for data or instructions. By way of example and not limitation, the memory 502 may be a hard disk drive (HDD), a floppy disk drive, a flash memory, an optical disk, a magneto-optical disk, a magnetic tape, or a universal serial bus (USB) drive, or a combination of two or more of these. Under appropriate circumstances, the memory 502 may include a removable or non-removable (or fixed) medium. Under appropriate circumstances, the memory 502 may be located either inside or outside a disaster recovery device of an integrated gateway. In a specific embodiment, the memory 502 is a non-volatile solid state memory.

The memory 502 may be a read-only memory (ROM), a random access memory (RAM), a magnetic disk storage medium device, an optical storage medium device, a flash memory device, or an electrical, optical, or other physical/tangible memory device. Therefore, typically, the memory includes one or more tangible (non-transient) computer-readable storage media (such as memory devices) encoded with software including computer executable instructions, and when the software is executed (for example, by one or more processors), it can perform the operation described with reference to the method according to one aspect of the present disclosure.

The processor 501 reads and executes the computer program instructions stored in the memory 502 to implement the method for building a photolithography model in any of the foregoing embodiments.

In one example, the device for building a photolithography model may further include a communication interface 503 and a bus 504. The processor 501, the memory 502, and the communication interface 503 are connected and communicate with each other through the bus 504.

The communication interface 503 is mainly configured to implement communication between various modules, apparatuses, units, and/or devices in the embodiments of the present application.

The bus 504 includes hardware, software, or both, coupling the components of the device for building a photolithography model together. By way of example and not limitation, the bus may include an accelerate graphical port (AGP) or other graphical buses, an enhanced industry standard architecture (EISA) bus, a front side bus (FSB), a hyper transport (HT) interconnect bus, an industry standard architecture (ISA) bus, an infinite bandwidth interconnect bus, a low pin count (LPC) bus, a memory bus, a micro channel architecture (MCA) bus, a peripheral component interconnect (PCI) bus, a PCI-Express (PCI-X) bus, a serial advanced technology attachment (SATA) bus, a video electronics standards association local bus (VLB), or other suitable buses, or a combination of two or more of these. Where appropriate, the bus 504 may include one or more buses. Although the embodiment of the present application describes and shows a specific bus, the present application considers any suitable bus or interconnect.

In addition, combined with the method for building a photolithography model in the foregoing embodiments, an embodiment of the present application may provide a computer storage medium for implementation. The computer storage medium stores computer program instructions; and the computer program instructions, when executed by a processor, implement the method for building a photolithography model in any of the foregoing embodiments.

An embodiment of the present application further provides a computer program product, including a computer program, the computer program, when executed by a processor, implementing the method for building a photolithography model in any of the foregoing embodiments.

It should be clear that the present application is not limited to the specific configuration and processing described above and shown in the drawings. For the sake of simplicity, detailed descriptions of known methods are omitted here. In the foregoing embodiments, several specific steps are described and shown as examples. However, the method process of the present application is not limited to the specific steps described and shown. After understanding the spirit of the present application, a person skilled in the art can make various changes, modifications and additions, or change the order between the steps.

The functional blocks shown in the structural diagram above may be implemented as hardware, software, firmware, or a combination thereof. When implemented as hardware, the functional blocks may be, for example, electronic circuits, ASIC, appropriate firmware, plug-ins, or feature cards. When implemented as software, the elements of the present application are programs or code segments used to perform required tasks. The programs or code segments may be stored in a machine-readable medium, or transmitted over a transmission medium or communication link through data signals carried in carrier waves. The “machine-readable medium” may include any medium that can store or transmit information. Examples of the machine-readable medium include an electronic circuit, a semiconductor memory device, an ROM, a flash memory, an erasable ROM (EROM), a floppy disc, a compact disc read-only memory (CD-ROM), an optical disc, a hard disc, a fiber optic medium, a radio frequency (RF) link, etc. The code segments may be downloaded via a computer network such as the Internet and Intranet.

It should also be noted that the exemplary embodiments mentioned in the present application describe some methods or systems based on a series of steps or devices. However, the present application is not limited to the order of the above steps, that is, the steps may be performed in the order mentioned in the embodiments or in an order different from that in the embodiments, or several steps may be performed simultaneously.

The above describes various aspects of the present disclosure with reference to the flowcharts and/or block diagrams of the method for building a photolithography model, device, medium, and product according to the embodiments of the present disclosure. It should be understood that each box in the flowcharts and/or block diagrams and a combination of boxes in the flowcharts and/or block diagrams may be implemented by computer program instructions. These computer program instructions may be provided to a processor of a general-purpose computer, a dedicated computer, or other programmable data processing apparatuses to produce a machine, which enables the instructions executed by the processor of the computer or other programmable data processing apparatuses to implement the functions/actions specified in one or more boxes of the flowchart and/or block view. Such a processor may be, but is not limited to a general-purpose processor, a dedicated processor, a special application processor, or a field programmable logic circuit. It can also be understood that each box in the block diagrams and/or flowcharts and a combination of boxes in the block diagrams and/or flowcharts may be implemented by dedicated hardware that executes specified functions or actions, or by a combination of dedicated hardware and computer instructions.

The above content is merely a specific implementation of the present application. A person skilled in the art may clearly understand that, for the convenience and simplicity of description, the specific working processes of the systems, modules, and units described above may refer to the corresponding processes in the foregoing method embodiments, and will not be repeated here. It should be understood that the protection scope of the present application is not limited thereto. A person skilled in the art can readily conceive various equivalent modifications or replacements within the technical scope disclosed by the present application, and these modifications or replacements shall fall within the protection scope of the present application.

What is claimed is:

1. A method for building a photolithography model, comprising:
acquiring a first photolithography model to be trained, a mask pattern sample, an actual photolithography pattern corresponding to the mask pattern sample, and an initial value of an alignment error;
iteratively adjusting a value of the alignment error and parameters of the first photolithography model until a cost function value satisfies an iteration stop condition, wherein the cost function value is determined based on a deviation value between a simulation pattern and the actual photolithography pattern; the simulation pattern is obtained by the first photolithography model simulating the mask pattern sample; the alignment error is for aligning the simulation pattern with the actual photolithography pattern; and
determining the current first photolithography model as a photolithography model under a condition that the cost function value satisfies the iteration stop condition.

2. The method for building a photolithography model according to claim 1, wherein the first photolithography model comprises a plurality of sub-models;
the iteratively adjusting a value of the alignment error and parameters of the first photolithography model until a cost function value satisfies an iteration stop condition, and determining the current first photolithography model as a photolithography model under a condition that the cost function value satisfies the iteration stop condition, comprise:
adjusting a first parameter group of the first photolithography model to obtain a corresponding second photolithography model under the first parameter group, wherein the first parameter group comprises internal parameters of the sub-models;
iteratively adjusting the value of the alignment error and a second parameter group of the second photolithography model until a first cost function value satisfies a first iteration stop condition, wherein the second parameter group comprises remaining parameters in the first photolithography model except the first parameter group; the first cost function value is determined based on a first simulation pattern and the actual photolithography pattern, and the first simulation pattern is obtained by the adjusted second photolithography model simulating the mask pattern sample; and
determining a second cost function value based on the mask pattern sample, the actual photolithography pattern, the finally obtained alignment error, and the finally obtained second photolithography model; under a condition that the second cost function value does not satisfy a second iteration stop condition, returning to the adjusting the first parameter group of the first photolithography model, until the second cost function value satisfies the second iteration stop condition; and
determining the finally obtained second photolithography model as the photolithography model when the second cost function value satisfies the second iteration stop condition.

3. The method for building a photolithography model according to claim 2, wherein the iteratively adjusting the value of the alignment error and a second parameter group of the second photolithography model until a first cost function value satisfies a first iteration stop condition comprises:
adjusting the value of the alignment error and the second parameter group of the second photolithography model;
inputting the mask pattern sample into the adjusted second photolithography model to obtain the first simulation pattern;
aligning the first simulation pattern with the actual photolithography pattern based on the adjusted alignment error;
acquiring a difference in key dimensions between the aligned first simulation pattern and actual photolithography pattern to obtain a first deviation;
determining the first cost function value based on the first deviation; and
under a condition that the first cost function value does not satisfy the first iteration stop condition, returning to the adjusting the value of the alignment error and the second parameter group of the second photolithography model until the first cost function value satisfies the first iteration stop condition.

4. The method for building a photolithography model according to claim 3, wherein the first iteration stop condition comprises: a difference between the first cost function value obtained in a current iteration and the first cost function value obtained in a previous iteration is less than a first threshold.

5. The method for building a photolithography model according to claim 3, wherein the adjusting the value of the alignment error and the second parameter group of the second photolithography model comprises:
adjusting the value of the alignment error and the second parameter group of the second photolithography model within a first value range according to a gradient-based optimization algorithm.

6. The method for building a photolithography model according to claim 4, wherein the adjusting the value of the alignment error and the second parameter group of the second photolithography model comprises:
adjusting the value of the alignment error and the second parameter group of the second photolithography model within a first value range according to a gradient-based optimization algorithm.

7. The method for building a photolithography model according to claim 2, wherein the determining a second cost function value based on the mask pattern sample, the actual photolithography pattern, the finally obtained alignment error, and the finally obtained second photolithography model comprises:
inputting the mask pattern sample into the finally obtained second photolithography model to obtain a second simulation pattern;
aligning the second simulation pattern with the actual photolithography pattern based on the finally obtained alignment error;
acquiring a difference in key dimensions between the aligned second simulation pattern and actual photolithography pattern to obtain a second deviation; and
determining the second cost function value based on the second deviation.

8. The method for building a photolithography model according to claim 7, wherein the second iteration stop condition comprises: a difference between the second cost function value obtained in a current iteration and the second cost function value obtained in a previous iteration is less than a second threshold.

9. The method for building a photolithography model according to claim 7, wherein the adjusting a first parameter group of the first photolithography model to obtain a corresponding second photolithography model under the first parameter group comprises:
adjusting the first parameter group of the first photolithography model within a second value range to obtain the second photolithography model according to a gradient-free nonlinear optimization algorithm.

10. The method for building a photolithography model according to claim 8, wherein the adjusting a first parameter group of the first photolithography model to obtain a corresponding second photolithography model under the first parameter group comprises:
adjusting the first parameter group of the first photolithography model within a second value range to obtain the second photolithography model according to a gradient-free nonlinear optimization algorithm.

11. A device for building a photolithography model, comprising: a processor and a memory storing computer program instructions, wherein
the processor, when executing the computer program instructions, implements the method for building a photolithography model according to claim 1.

12. A device for building a photolithography model, comprising: a processor and a memory storing computer program instructions, wherein
the processor, when executing the computer program instructions, implements the method for building a photolithography model according to claim 2.

13. A device for building a photolithography model, comprising: a processor and a memory storing computer program instructions, wherein
the processor, when executing the computer program instructions, implements the method for building a photolithography model according to claim 3.

14. A device for building a photolithography model, comprising: a processor and a memory storing computer program instructions, wherein
the processor, when executing the computer program instructions, implements the method for building a photolithography model according to claim 4.

15. A device for building a photolithography model, comprising: a processor and a memory storing computer program instructions, wherein
the processor, when executing the computer program instructions, implements the method for building a photolithography model according to claim 5.

16. A device for building a photolithography model, comprising: a processor and a memory storing computer program instructions, wherein
the processor, when executing the computer program instructions, implements the method for building a photolithography model according to claim 6.

17. A device for building a photolithography model, comprising: a processor and a memory storing computer program instructions, wherein
the processor, when executing the computer program instructions, implements the method for building a photolithography model according to claim 7.

18. A device for building a photolithography model, comprising: a processor and a memory storing computer program instructions, wherein
the processor, when executing the computer program instructions, implements the method for building a photolithography model according to claim 8.

19. A non-transitory computer-readable storage medium, wherein the computer-readable storage medium stores computer program instructions, and the computer program instructions, when executed by a processor, implement the method for building a photolithography model according to claim 1.

20. A computer program product, wherein instructions in the computer program product, when executed by a processor of an electronic device, enable the electronic device to perform the method for building a photolithography model according to claim 1.
